(19) United States
(12) Patent Application Publication
(10) Pub. No.: US 2026/0246430 A1
(43) Pub. Date: Aug. 20, 2026

(54) ANALOG FRONT END WITH COMPENSATED OPEN LOOP STAGE

(71) Applicant: STMicroelectronics International N.V., Geneva (CH)

(72) Inventors: Alessio Emanuele Vergani, Milano (IT); Andrea Bertucca, Cava Manara (IT); Antonio Santipo, Cinisello Balsamo (IT)

(21) Appl. No.: 19/055,160

(22) Filed: Feb. 17, 2025

(51) Int. Cl. H03F 1/22; H03F 1/32; H03F 3/45

(52) U.S. Cl. CPC H03F 1/223; H03F 1/3211; H03F 3/45085; H03F 3/45183; H03F 3/45488; H03F 3/45636; H03F 2203/45288

(57) ABSTRACT

According to an embodiment, an analog front-end circuit includes an open-loop gain stage and a closed-loop stage. The open-loop gain stage includes a first differential transistor pair with first width-to-length ratios and load resistors coupled to its outputs. The closed-loop stage includes a second differential transistor pair with second width-to-length ratios scaled by a factor 1/k relative to the first width-to-length ratios, a reference resistor generating a differential voltage, and current mirrors. The current mirrors steer current through the second differential transistor pair based on the differential voltage and scale the current by factor k to generate bias current for the open-loop gain stage. The analog front-end circuit can be implemented in hard disk drive pre-amplifiers to process fly height sensors signals.

### TECHNICAL FIELD

The present disclosure generally relates to electronic systems and, in particular embodiments, to an analog front-end with a compensated open loop stage.

### BACKGROUND

Hard disk drives in modern data storage systems rely on read/write heads suspended above rapidly spinning magnetic disks to store and retrieve data. The heads contain multiple elements, including read sensors, write transducers, and heaters that work together to enable reliable data recording and playback.

The spacing between the head elements and disk surface, known as fly height, is a parameter that directly impacts drive performance and reliability. Current hard drives operate with a nominal head-to-disk spacing of 10-20 nanometers during idle operation. To optimize read and write performance, thermal actuators in the heads can locally heat and deform specific regions to reduce active elements' spacing to approximately 1 nanometer. Maintaining precise control of this spacing is advantageous as excessive fly height leads to signal degradation and errors, while insufficient spacing risks devastating head-disk contact.

Heat-assisted magnetic recording (HAMR) technology represents an advancement in magnetic storage that enables higher data density. HAMR drives incorporate laser elements in the write heads that briefly heat localized areas of the disk surface during write operations. This heating temporarily reduces the magnetic coercivity of the media, allowing narrower data tracks to be written with existing write field strengths. The laser power output is controlled to heat the target area and consistent track widths. However, semiconductor lasers can experience mode hops—sudden jumps in emission frequency and power output that may vary by several percentage points from nominal levels. It is desirable to detect the power variations and compensate for them immediately to maintain write quality.

Monitoring and controlling parameters like fly height, disk surface defects, and laser power variations typically depend on specialized sensors integrated into the drive heads. These sensors exhibit conductivity changes proportional to the physical parameters being measured. Small sensor signals require analog front-end circuits to amplify and filter. Challenges for these circuits include maintaining stable gain across wide ranges of process variations, supply voltages, and operating temperatures while simultaneously achieving low noise, wide bandwidth, and large dynamic range. The analog front-end performance impacts the drive's ability to accurately measure and control the nanometer-scale mechanical tolerances and precise power levels needed for reliable high-density magnetic recording.

### SUMMARY

Technical advantages are generally achieved by embodiments of this disclosure, which describe an analog front-end with a compensated open loop stage.

A first aspect relates to an analog front-end circuit, comprising an open-loop gain stage including a first differential transistor pair comprising a first transistor and a second transistor with first width-to-length ratios, load resistors coupled to outputs of the first transistor and the second transistor, and a current sink coupled to source terminals of the first transistor and the second transistor; and a closed-loop stage including a second differential transistor pair comprising a third transistor and a fourth transistor with second width-to-length ratios scaled by a factor 1/k relative to the first width-to-length ratios, a reference resistor coupled to receive a first current to generate a differential voltage across control terminals of the third transistor and the fourth transistor, wherein the reference resistor matches a resistor type of the first load resistors, a first current mirror and a second current mirror coupled to steer a second current through the second differential transistor pair based on the differential voltage, and a third current mirror configured to scale the second current by the factor k to generate a bias current for the current sink.

A second aspect relates to a method of operating an analog front-end circuit, the method comprising generating a differential voltage across control terminals of a first differential transistor pair by flowing a first current through a reference resistor; steering a second current through the first differential transistor pair based on the differential voltage; mirroring the second current through first and second current mirrors; scaling the mirrored second current by a factor k through a third current mirror; providing the scaled second current to a current sink coupled to a second differential transistor pair, wherein the second differential transistor pair has transistors with width-to-length ratios k times larger than transistors in the first differential transistor pair; receiving differential input signals at control terminals of the second differential transistor pair; and generating differential output voltages across load resistors coupled to outputs of the second differential transistor pair, wherein the load resistors match a resistor type of the reference resistor.

A third aspect relates to an analog front-end circuit, comprising an open-loop gain stage including a first and second complementary transistor pairs configured as inverters, first and second resistors coupled to set DC operating points for the inverters, and first and second RC networks coupled to provide AC coupling for differential input signals; and a closed-loop stage including a differential transistor pair having transistors with width-to-length ratios scaled by a factor 1/k relative to transistors in the first and second complementary transistor pairs, a reference resistor coupled to receive a first current to generate a differential voltage, first and second current mirrors coupled to steer a second current through the differential transistor pair based on the differential voltage, third and fourth complementary transistor pairs biased at ground plus a base-to-emitter voltage, and a third current mirror configured to scale the second current by the factor k to generate bias currents for the first and second complementary transistor pairs.

Embodiments can be implemented in hardware, software, or any combination thereof.

### BRIEF DESCRIPTION OF THE DRAWINGS

For a more complete understanding of the present disclosure and the advantages thereof, reference is now made to the following descriptions taken in conjunction with the accompanying drawings, in which:

FIG. 1 is a block diagram of a circuit for biasing a resistive sensor (R_{SNS}) and reading a voltage signal (V_{SNS});

FIG. 2 is a block diagram of an embodiment analog front-end circuit;

FIG. 3 is a simplified and generalized schematic of an embodiment analog front-end circuit;

FIG. 4 is a schematic of an embodiment closed-loop stage;

FIG. 5 is a schematic of an embodiment closed-loop stage;

FIG. 6 is a schematic of an embodiment open-loop gain stage;

FIG. 7 is a schematic of an embodiment closed-loop stage;

FIG. 8 is a schematic of an embodiment open-loop gain stage;

FIG. 9 is a schematic of an embodiment open-loop gain stage;

FIG. 10 is a schematic of an embodiment open-loop gain stage;

FIG. 11 is a schematic of an embodiment closed-loop stage;

FIG. 12 is a schematic of an embodiment closed-loop stage;

FIG. 13 is a flowchart of an embodiment method for operating an analog front-end circuit in a hard disk drive pre-amplifier; and

FIG. 14 is a block diagram of a pre-amplifier that is placed on the disk drive head stack assembly of a hard disk drive.

### DETAILED DESCRIPTION OF ILLUSTRATIVE EMBODIMENTS

This disclosure provides many applicable inventive concepts that can be embodied in a wide variety of specific contexts. The particular embodiments are merely illustrative of specific configurations and do not limit the scope of the claimed embodiments. Features from different embodiments may be combined to form further embodiments unless noted otherwise. Various embodiments are illustrated in the accompanying drawing figures, where identical components and elements are identified by the same reference number, and repetitive descriptions are omitted for brevity.

Variations or modifications described in one of the embodiments may also apply to others. Further, various changes, substitutions, and alterations can be made herein without departing from the spirit and scope of this disclosure as defined by the appended claims.

While the inventive aspects are described primarily in the context of hard disk drive preamplifier circuits for fly height sensing, head-disk contact detection, and laser power monitoring, it should also be appreciated that these inventive aspects may also apply to other analog front-end applications requiring precise gain control, low noise, and wide bandwidth performance. In particular, aspects of this disclosure may similarly apply to any system requiring constant gain and low noise amplification across wide ranges of process, voltage, and temperature variations.

Embodiments of the disclosure provide analog front-end circuits that achieve gain control while maintaining low noise and wide bandwidth performance. The architecture incorporates an open-loop gain stage coupled with a closed-loop compensation stage. The open-loop gain stage amplifies input signals using a first differential transistor pair with associated load resistances. A closed-loop stage compensates for variability in the open-loop gain stage by utilizing a second differential transistor pair configured as a scaled copy of the first differential transistor pair, with device geometries and currents scaled by a factor k.

The closed-loop stage generates a bias current based on an imbalance voltage applied to inputs of the second differential transistor pair. Through current mirrors and scaling, the bias current from the closed-loop stage controls the operating point of the first differential pair in the open-loop stage. By matching device types and scaling ratios between the open-loop and closed-loop stages, consistent gain can be maintained across process, voltage, and temperature (PVT) variations while preserving the low noise and wide bandwidth benefits of the open-loop architecture.

Aspects of the disclosure include techniques for improving performance and stability. Startup current injection helps establish proper operating points during power-up. Degeneration transistors added to the differential pairs enhance matching and increase linear operating range. AC coupling capacitors enable operation with different DC input levels while maintaining consistent gain at signal frequencies. Gain boosting through capacitive feedback provides increased signal amplification and improved signal-to-noise ratio.

Additional embodiments incorporate cascode devices in the signal paths to improve common mode and power supply rejection. Folded output stages increase dynamic range by allowing greater signal swing. The differential pairs may utilize metal-oxide silicon field effect transistors (MOSFETs), bipolar transistors, or combinations of different device technologies depending on performance requirements.

The analog front-end architecture adapts to different gain stage topologies. Vertical mixed-technology implementations combine MOSFET and bipolar devices in differential pairs. Inverter-based gain stages use complementary p-channel and n-channel MOSFET devices with mirrored bias currents. The combination of precise gain control from the closed-loop stage with optimized open-loop signal paths enables high-performance analog front-end circuits to maintain a consistent gain set to a target value while achieving input-referred noise in the order of ~nV/√Hz over a bandwidth that can reach hundreds of MHz. These and additional details are further discussed below.

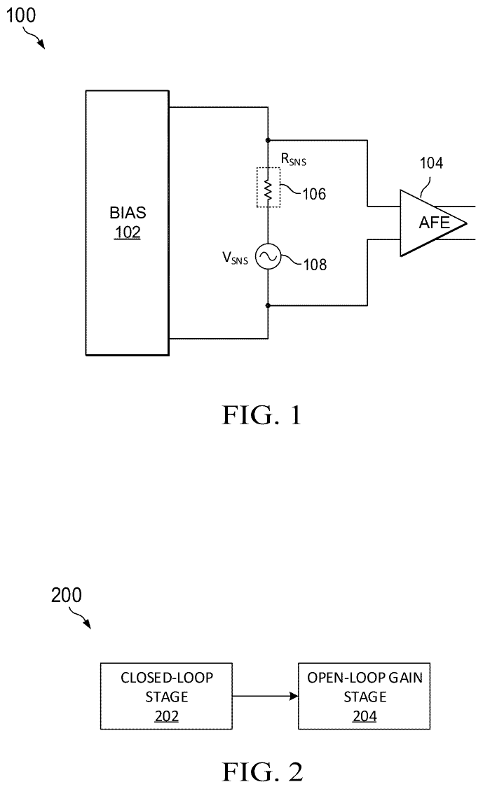

FIG. 1 illustrates a block diagram of a circuit 100 for biasing a resistive sensor (R_{SNS}) 106 and reading a voltage signal (V_{SNS}) 108. Circuit 100 includes a biasing circuit 102 and an analog front-end (AFE) circuit 104 coupled to the resistive sensor (R_{SNS}) 106, which may (or may not) be arranged as shown. Circuit 100 may include additional components not shown. A detailed description of a possible implementation of circuit 100 is provided in U.S. Pat. No. 10,965,254, which is incorporated herein by reference in its entirety.

The spacing between the read/write head and the disk surface in hard disk drive systems impacts drive performance. A heater element in the head assembly elevates the temperature of a portion of the flying head. The thermal actuation reduces the separation between the active read/write elements and the disk surface. This thermal actuation can reduce the normal separation of 10-20 nanometers to approximately 1 nanometer for optimum performance. Operating at larger spacings results in excessive read and write errors, while insufficient spacing can cause catastrophic damage from head-disk contact.

In embodiments, the resistive sensor (R_{SNS}) 106 monitors the head-disk spacing when implemented as a thermal conductivity sensor. When placed on the read/write head assembly, the resistive sensor (R_{SNS}) 106 experiences resistance variations as the head approaches the disk surface, which acts as a heat sink. These resistance changes generate the voltage signal (V_{SNS}) that indicates the relative spacing between the head and the disk.

The analog front-end circuit 104 amplifies the sensing voltage (V_{SNS}). The output of the analog front-end circuit 104 couples to a controller that processes the amplified sensing voltage (V_{SNS}) to determine the fly height of the hard disk drive. Processing signals from the resistive sensor (R_{SNS}) 106 allows monitoring of head-disk contact and proximity. The voltage signal (V_{SNS}) passes through low-noise analog front-end circuits to extract useful measurements.

Processing the sensing voltage (V_{SNS}) through the analog front-end circuit 104 presents several technical challenges. One involves maintaining constant and stable gain across process, voltage, and temperature variations. Traditional closed-loop architectures can guarantee gain stability but introduce complexity that can degrade other performance parameters.

A second challenge is achieving low noise performance targets in the order of ~nV/√Hz in the signal amplification path. Well-known gain stages implemented with MOSFETs or bipolar transistors and properly designed may achieve these low noise requirements but exhibit significant transconductance (gm) variations across operating conditions. These variations can make maintaining stable gain difficult and lead to gain variability.

A third challenge involves a wide bandwidth while maintaining stable gain. Complex feedback loops commonly used for gain stabilization tend to limit frequency response, and bandwidth requirements can conflict with traditional approaches to maintaining constant gain through closed-loop architectures, maintaining reasonable power consumption.

A fourth challenge centers on accommodating input signals with a wide dynamic range for the gain stage while maintaining low noise performance. Design choices of the circuit to handle larger signal swings can conflict with the noise performance, creating competing design constraints between dynamic range and noise specifications.

FIG. 2 illustrates a block diagram of an embodiment analog front-end circuit 200, which may be implemented in the analog front-end (AFE) circuit 104. Analog front-end circuit 200 includes a closed-loop stage 202 and an open-loop gain stage 204, which may (or may not) be arranged as shown. Analog front-end circuit 200 may include additional components not shown, such as filters or additional gain stages.

The analog front-end circuit 200 addresses the challenges of processing the sensing voltage (V_{SNS}) through an architecture that separates gain control from signal amplification. This separation allows optimization of competing performance requirements that traditionally conflict in conventional designs.

The architecture addresses the challenges of maintaining constant gain across PVT variations while achieving low noise, wide bandwidth, and large dynamic range. Rather than employing complex feedback loops in the signal path that can degrade noise and bandwidth performance, the architecture utilizes a closed-loop stage 202 for gain stabilization while preserving a clean signal path through the open-loop gain stage 204.

The closed-loop stage 202 compensates for process, voltage, and temperature variations by monitoring a gain stage copy (e.g., a copy of the open-loop gain stage 204) and generating command signals to control the open-loop gain stage 204. The command signals from the closed-loop stage 202 may include bias currents or control voltages that establish operating points in the open-loop gain stage 204. These signals adjust dynamically to compensate for variations in device parameters and operating conditions. The open-loop gain stage 204 amplifies input signals using minimal active components to achieve wide bandwidth and low noise performance.

The closed-loop stage 202 includes a gain stage copy replicating the core amplification elements of the open-loop gain stage 204. Through this architecture, the closed-loop stage 202 compensates for manufacturing variability and temperature effects without introducing additional components into the main signal path through the open-loop gain stage 204.

The gain stage copy employs matched devices and scaling factors relative to the open-loop gain stage 204, allowing accurate tracking of parameter variations while optimizing power and area consumptions. By operating under the same conditions as the open-loop gain stage 204, the gain stage copy provides representative feedback for compensation while remaining isolated from the main signal path.

Combining closed-loop gain control with open-loop signal amplification allows the analog front-end circuit 200 to maintain stable gain across PVT variations while preserving bandwidth and noise performance. This architecture avoids the traditional tradeoffs between gain stability and noise and bandwidths in conventional closed-loop amplifiers.

Accordingly, a new architecture for preamplifier front-end circuits is proposed that addresses conventional challenges through a combination of open-loop and closed-loop stages. The open-loop gain stage, constructed with minimal active components, amplifies the signal while achieving wide bandwidth and low noise performance. A separate closed-loop stage controls gain stability across PVT variations without compromising the performance benefits of the open-loop stage. This approach overcomes the limitations of traditional architectures, where closed-loop designs typically offer precise gain control but suffer from limited bandwidth and degraded noise performance.

The proposed architecture demonstrates significant advantages over prior solutions, achieving gain stability (e.g., within ±1 dB) across PVT variations while maintaining noise performance in the order of ~nV/√Hz. The circuit can operate with bandwidth exceeding hundreds of MHz and can be designed to accommodate input signals in the order of hundreds of mV with output signals in the order of Volts. These specifications make the architecture suitable for hard disk drive applications and any system requiring precise gain control with low noise and wide bandwidth performance.

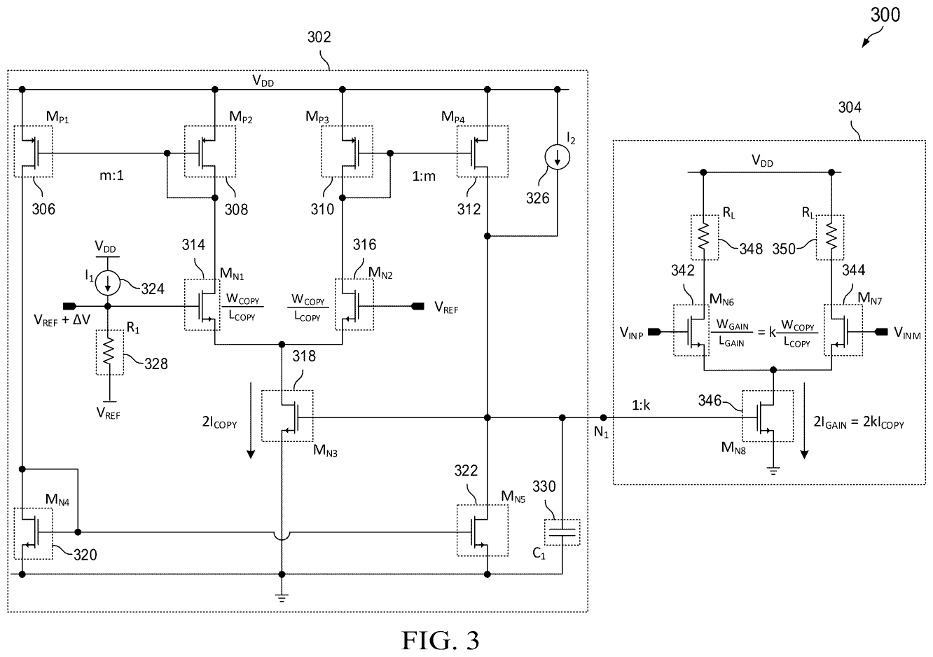

FIG. 3 illustrates a simplified and generalized schematic of an embodiment analog front-end circuit 300, which may be implemented in the analog front-end (AFE) circuit 104. Analog front-end circuit 300 includes a closed-loop stage 302 coupled to an open-loop gain stage 304 at node (N₁), which may (or may not) be arranged as shown. The closed-loop stage 302 and the open-loop gain stage 304 may be implemented, respectively, as the closed-loop stage 202 and the open-loop gain stage 204 of FIG. 2. Analog front-end circuit 300 may include additional components not shown, such as filters or additional gain stages.

The closed-loop stage 302 includes a first p-channel transistor (M_{P1}) 306, a second p-channel transistor (M_{P2}) 308, a third p-channel transistor (M_{P}_{₃}) 310, a fourth p-channel transistor (M_{P4}) 312, a first n-channel transistor (M_{N1}) 314, a second n-channel transistor (M_{N2}) 316, a third n-channel transistor (M_{N3}) 318, a fourth n-channel transistor (M_{N4}) 320, a fifth n-channel transistor (M_{N5}) 322, a first current source (I₁) 324, a second current source (I₂) 326, a first resistor (R₁) 328, and a first capacitor (C₁) 330, which may (or may not) be arranged as shown. Closed-loop stage 302 may include additional components not shown.

The open-loop gain stage 304 includes a sixth n-channel transistor (M_{N6}) 342, a seventh n-channel transistor (M_{N7}) 344, an eight n-channel transistor (M_{N8}) 346, a first load resistor (R_{L}) 348, and a second load resistor (R_{L}) 350, which may (or may not) be arranged as shown. The open-loop gain stage 304 may include additional components not shown.

The first p-channel transistor (M_{P1}) 306 and the second p-channel transistor (M_{P2}) 308 form a first current mirror with a ratio of m to 1 (m:1). The fourth p-channel transistor (M_{P4}) 312 and the third p-channel transistor (M_{P3}) 310 form a second current mirror with a ratio of m to 1 (m:1).

The first and the second current mirrors creates a current scaling network. When the differential pair formed by the first n-channel transistor (M_{N1}) 314 and the second n-channel transistor (M_{N2}) 316 steers current in response to ΔV, these current mirrors translate the differential current into a single-ended signal while maintaining accurate current ratios. The mirror ratios ensure that changes in the differential current are properly scaled and conveyed to control the bias current generation through the third n-channel transistor (M_{N3}) 318.

The first n-channel transistor (M_{N1}) 314 is a copy of the sixth n-channel transistor (M_{N6}) 342 scaled by a factor k. Accordingly, the ratio of the width (W_{COPY}) and length (L_{COPY}) of the first n-channel transistor (M_{N1}) 314 scaled by the factor k equals the ratio of the width (W_{GAIN}) and length (L_{GAIN}) of the sixth n-channel transistor (M_{N6}) 342

$$( i . e . , \frac{{W}_{GAIN}}{{L}_{GAIN}} = k \times \frac{{W}_{COPY}}{{L}_{COPY}} ) .$$

Likewise, the second n-channel transistor (M_{N2}) 316 is a copy of the seventh n-channel transistor (M_{N7}) 344 scaled by a factor k. Accordingly, the ratio of the width (W_{COPY}) and length (L_{COPY}) of the second n-channel transistor (M_{N2}) 316 scaled by the factor k equals the ratio of the width (W_{GAIN}) and length (L_{GAIN}) of the seventh n-channel transistor (M_{N7}) 344

$$( i . e . , \frac{{W}_{GAIN}}{{L}_{GAIN}} = k \times \frac{{W}_{COPY}}{{L}_{COPY}} ) .$$

The closed-loop stage 302 generates a differential voltage ΔV across the control terminals of the differential pair formed by the first n-channel transistor (M_{N1}) 314 and the second n-channel transistor (M_{N2}) 316, where ΔV is generated by the first current source (I₁) 324 across the first resistor (R₁) 328 (i.e., ΔV=I₁×R₁).

The control terminals of the differential pair formed by the sixth n-channel transistor (M_{N6}) 342 and the seventh n-channel transistor (M_{N7}) 344 are set to, respectively, the positive input voltage (V_{INP}) and the negative input voltage (V_{INM}).

The closed-loop stage 302 forces a bias current (2×I_{COPY}) in the differential pair formed by the first n-channel transistor (M_{N1}) 314 and the second n-channel transistor (M_{N2}) 316. This bias current (2×I_{COPY} is such that the differential current flowing through the differential pair formed by the first n-channel transistor (M_{N1}) 314 and the second n-channel transistor (M_{N2}) 316 is, by applying ΔV, directly proportional to current (I₂) generated by the second current source (I₂) 326. This led to a controlled gm of the differential couple. The bias current (2×I_{COPY}) is mirrored and scaled by factor k (i.e., 2×I_{GAIN}=2×k×I_{COPY}) to bias the differential pair formed by the sixth n-channel transistor (M_{N6}) 342 and the seventh n-channel transistor (M_{N7}) 344 in the open-loop gain stage 304.

The eight n-channel transistor (M_{N8}) 346 is a current sink in the open-loop gain stage 304, establishing a bias current of 2×I_{GAIN} (which equals 2×k×I_{COPY}). This current sink configuration maintains proper current density in the differential pair formed by the sixth n-channel transistor (M_{N6}) 342 and the seventh n-channel transistor (M_{N7}) 344 by ensuring their source terminals are held at an appropriate voltage. The scaling factor k between I_{GAIN} and I_{COPY} maintains consistent transconductance ratios between the closed-loop stage 302 and open-loop gain stage 304.

The open-loop gain stage 304 implements a transconductance-resistance (gm_{R}) gain stage through the differential pair formed by the sixth n-channel transistor (M_{N6}) 342 and the seventh n-channel transistor (M_{N7}) 344 and the first load resistor (R_{L}) 348 and the second load resistor (R_{L}) 350. The transconductance (gm) of the sixth n-channel transistor (M_{N6}) 342 and the seventh n-channel transistor (M_{N7}) 344 converts the differential input voltage (V_{INP}−V_{INM}) into a differential current. This current flows through the first load resistor (R_{L}) 348 and the second load resistor (R_{L}) 350 to generate an output voltage.

The overall voltage gain of the open-loop gain stage 304 is determined by the product of the transconductance (gm) and load resistance (R_{L}). By controlling the transconductance through current scaling from the closed-loop stage 302 and matching the load resistance (R_{L}) to a scaled version of the first resistor (R₁) 328, the transconductance-resistance (gm_{R}) gain stage maintains consistent gain across PVT variations while achieving low noise and wide bandwidth due to its simple two-transistor differential pair topology.

The transconductance (gm) relationship between the open-loop gain stage 304 and closed-loop stage 302 follows from the device physics of the transistors. The transconductance of the gain stage (gm_{GAIN}) follows the equation:

$${gm}_{GAIN} = \sqrt{2 \times {μ}_{n} \times {C}_{OX} \times \frac{{W}_{GAIN}}{{L}_{GAIN}} \times {I}_{GAIN}} ,$$

where μₙ is the electron mobility, Cₒₓ is the oxide capacitance,

$$\frac{{W}_{GAIN}}{{L}_{GAIN}}$$

is the width-to-length ratio, and I_{GAIN} is the bias current.

The width-to-length ratios in the closed-loop stage 302 are scaled by factor k

$$( \frac{{W}_{GAIN}}{{L}_{GAIN}} = k \times \frac{{W}_{COPY}}{{L}_{COPY}} ) ,$$

the currents are scaled by the same factor k (I_{GAIN}=k×I_{COPY}), and the process parameters are matched (μ_{n_COPY}×C_{OX_COPY}=μ_{n_GAIN}×C_{OX_GAIN}). As a result, the transconductance of the gain stage (gm_{GAIN}) equals k times the transconductance of the copy stage (gm_{COPY}).

The closed-loop gain (G_{LOOP}) establishes the current (I_{COPY} such that:

$${I}_{1} \times {R}_{1} \times \frac{{gm}_{COPY}}{2} \times 2 \times m = {I}_{2} ,$$

resulting in the transconductance of the copy stage (gm_{COPY}) to be:

$$\frac{{gm}_{COPY}}{2} \times 2 \times m = {I}_{2} ,$$

The gain of the differential stage is determined by:

$$\frac{{gm}_{COPY}}{2} \times 2 \times {R}_{L} ,$$

yields an overall gain (G) for the open-loop gain stage 304:

$$G = {gm}_{GAIN} \times {R}_{L} = \frac{k \times {I}_{2} \times {R}_{L}}{m \times {I}_{1} \times {R}_{1}} .$$

The scaling factors k and m are fixed values independent of process and temperature variations. Once that target gm_{GAIN} and then targe

$$\frac{{W}_{GAIN}}{{L}_{GAIN}}$$

and I_{GAIN} are defined based on design requirements, the current mirror factor m and the scaling factor k can be adjusted. Larger k value reduces copied device sizes and power consumption but impacts matching, while lower k values improve matching but increase area and power consumption. Example values for k are 3, 5, or 10.

To maintain consistent gain across process and temperature variations, I₂×R_{L} tracks proportionally with I₁×R₁. This tracking can be achieved by implementing I₁ and I₂ with matched current sources and selecting the first resistor (R₁) 328, the first load resistor (R_{L}) 348, and the second load resistor (R_{L}) 350 from the same resistor type. By matching current sources and resistors, variations in process and temperature cancel out, resulting in a gain that remains stable across operating conditions.

The fourth n-channel transistor (M_{N4}) 320, the fifth n-channel transistor (M_{N5}) 322, and the first capacitor (C₁) 330 provide biasing functions and stability, respectively, in the closed-loop stage 302. The fourth n-channel transistor (M_{N4}) 320 operates as a transdiode device that reads the current from (M_{P1}) 306. The fifth n-channel transistor (M_{N5}) 322 mirrors the current read from (MN4) 320, which is to be compared by the loop with the current from (M_{P4}) 312 and (I₂) 326. The first capacitor (C₁) 330 provides frequency compensation for the closed loop, ensuring stable operation by controlling the loop response across frequency.

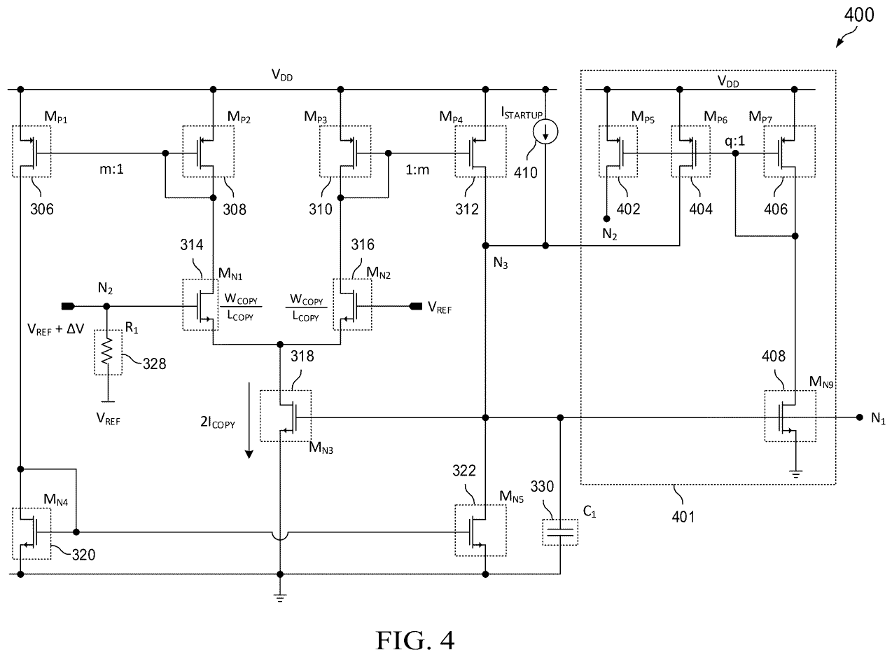

FIG. 4 illustrates a schematic of an embodiment closed-loop stage 400, which may be implemented as the closed-loop stage 202 of FIG. 2. Closed-loop stage 400 couples to the open-loop gain stage 204 at node (N₁). The closed-loop stage 400 builds upon the architecture of closed-loop stage 302 of FIG. 3, with modifications to improve performance across operating conditions. The functional and structural descriptions of components previously discussed with respect to FIG. 3 are not repeated here for the brevity of discussion.

The closed-loop stage 400 removes the fixed first current source (I₁) 324 and the second current source (I₂) 326 of FIG. 3, replacing them with an active current generation network 401 comprising a fifth p-channel transistor (M_{P5}) 402, a sixth p-channel transistor (M_{P6}) 404, a seventh p-channel transistor (M_{P7}) 406, and a ninth n-channel transistor (M_{N9}) 408, which may (or may not) be arranged as shown.

The active current generation network 401 generates currents that dynamically adjust based on operating conditions from the current (2×I_{COPY} flowing through the third n-channel transistor (M_{N3}) 318 using the ninth n-channel transistor (M_{N9}) 408.

The seventh p-channel transistor (M_{P7}) 406 participates in two current mirror configurations. It forms a third current mirror with the fifth p-channel transistor (M_{P5}) 402 and a fourth current mirror with the sixth p-channel transistor (M_{P6}) 404. Both current mirrors are configured with a ratio of q to 1 (q:1), where q represents the scaling factor. Through these current mirror relationships, the circuit can establish current scaling for the dynamic adjustment of ΔV and the current (I_{COPY}).

The current generated by the third current mirror is provided to the second node (N₂), whereas the current generated by the fourth current mirror is provided to the third node (N₃). Accordingly, in the closed-loop stage 400, ΔV is generated by the third current mirror across the first resistor (R₁) 328, resulting in a more precise gain of the open-loop stage. The active current generation network 401 results in the differential pair formed by the first n-channel transistor (M_{N1}) 314 and the second n-channel transistor (M_{N2}) 316 to operate with a more consistent unbalanced signal condition.

As the transconductance (gm) increases at lower temperatures, the active current generation network 401 compensates by reducing the current (I_{COPY}), which results in lower overdrive voltage (V_{OV}) for the transistors. This reduction in ΔV tracks with the decreased linear operating region of the differential pair at lower temperatures (e.g., at −40C).

The dynamic current adjustment through the fifth p-channel transistor (M_{P5}) 402, the sixth p-channel transistor (M_{P6}) 404, the seventh p-channel transistor (M_{P7}) 406, and the ninth n-channel transistor (M_{N9}) 408 replaces the fixed currents previously provided by the first current source (I₁) 324 and the second current source (I₂) 326. In embodiments, startup currents are used to start the closed-loop stage 400. Here, only a single startup current 410 is shown.

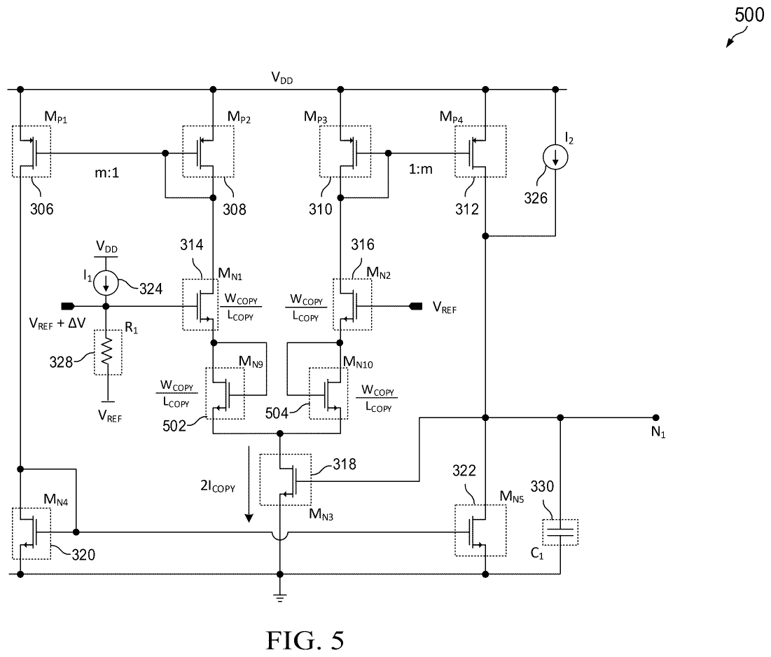

FIG. 5 illustrates a schematic of an embodiment closed-loop stage 500, which may be implemented as the closed-loop stage 202 of FIG. 2. Closed-loop stage 500 couples to the open-loop gain stage 204 at node (N₁). The closed-loop stage 500 builds upon the architecture of closed-loop stage 302 of FIG. 3, with modifications to improve matching in the differential pair in the closed-loop stage. The functional and structural descriptions of components previously discussed with respect to FIG. 3 are not repeated here for the brevity of discussion.

The closed-loop stage 500 adds a ninth n-channel transistor (M_{N9}) 502 and a tenth n-channel transistor (M_{N10}) 504 configured as diode-connected devices. The ninth n-channel transistor (M_{N9}) 502 couples to the first n-channel transistor (M_{N1}) 314, while the tenth n-channel transistor (M_{N10}) 504 couples to the second n-channel transistor (M_{N2}) 316. The ninth n-channel transistor (M_{N9}) 502 and the tenth n-channel transistor (M_{N10}) 504 are designed with the same width-to-length ratio

$$( \frac{{W}_{COPY}}{{L}_{COPY}} )$$

as the first n-channel transistor (M_{N1}) 314 and the second n-channel transistor (M_{N2}) 316.

Adding the ninth n-channel transistor (M_{N9}) 502 and the tenth n-channel transistor (M_{N10}) 504 enhances matching in the differential pair formed by the first n-channel transistor (M_{N1}) 314 and the second n-channel transistor (M_{N2}) 316. These diode-connected devices reduce the differential pair's effective transconductance (gm) while increasing its linear operating region. The reduced transconductance (gm) results from the series connection of matched devices, which doubles the effective voltage-to-current gain relationship of the differential couple of the open-loop gain stage 304 in FIG. 3.

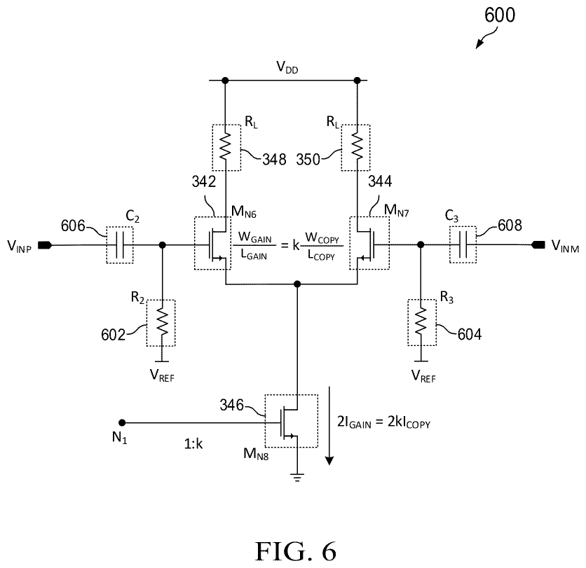

FIG. 6 illustrates a schematic of an embodiment open-loop gain stage 600, which may be implemented as the open-loop gain stage 204 of FIG. 2. The open-loop gain stage 600 couples to the closed-loop stage 202 at node (N₁). The open-loop gain stage 600 builds upon the architecture of the open-loop gain stage 304 of FIG. 3, using an AC coupled differential pair. The functional and structural descriptions of components previously discussed with respect to FIG. 3 are not repeated here for the brevity of discussion.

The open-loop gain stage 600 adds RC filtering at each input. A first RC network includes a second resistor (R₂) 602 and a second capacitor (C₂) 606 coupled to the positive input voltage (V_{INP}). A second RC network includes a third resistor (R₃) 604 and a third capacitor (C₃) 608 coupled to the negative input voltage (V_{INM}). In embodiments, these RC networks provide high-pass filtering and DC-level shifting.

The RC filters allow the open-loop gain stage 600 to operate with different DC levels at the positive input voltage (V_{INP}) and the negative input voltage (V_{INM}) while maintaining consistent differential gain for AC signals. The RC filters block DC and low-frequency components, providing proper biasing for the sixth n-channel transistor (M_{N6}) 342 and the seventh n-channel transistor (M_{N7}) 344 through resistors the second resistor (R₂) 602 and the third resistor (R₃) 604, respectively.

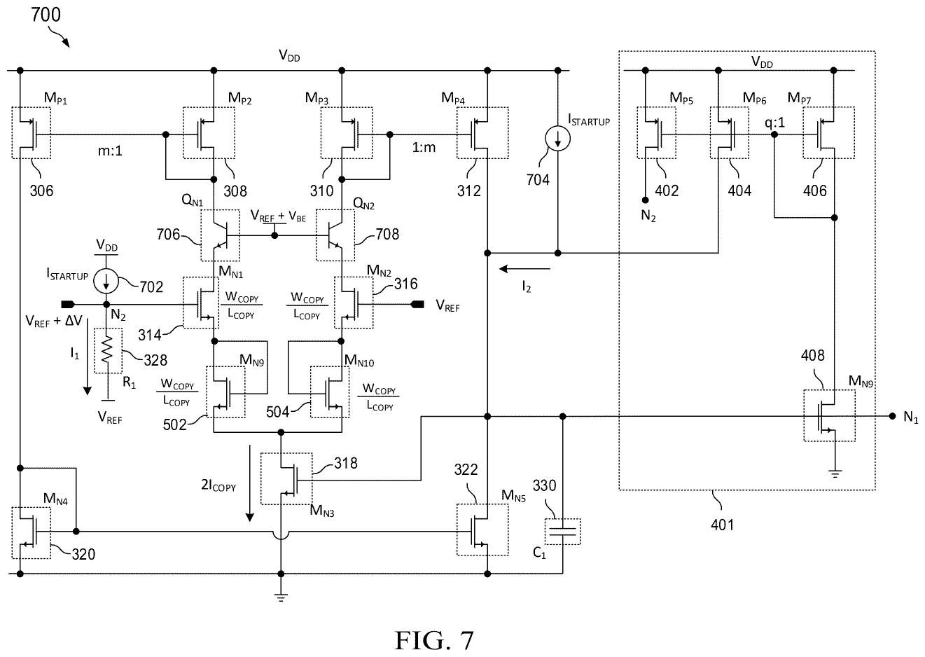

FIG. 7 illustrates a schematic of an embodiment closed-loop stage 700, which may be implemented as the closed-loop stage 202 of FIG. 2. Closed-loop stage 700 couples to the open-loop gain stage 800 at node (N₁). The closed-loop stage 700 builds upon the architecture of closed-loop stage 302 of FIG. 3 and the closed-loop stage 400 of FIG. 4. The functional and structural descriptions of components previously discussed with respect to FIGS. 3 and 4 are not repeated here for the brevity of discussion.

The closed-loop stage 700 replaces the first current source (I₁) 324 with an optional first startup current (I_{STARTUP}) 702 and replaces the second current source (I₂) 326 with a second startup current (I_{STARTUP}) 704. The startup currents are employed when starting the closed-loop stage 700. The closed-loop stage 700 adds a first NPN transistor (Q_{N1}) 706 and a second NPN transistor (Q_{N2}) 708 arranged in cascode configuration.

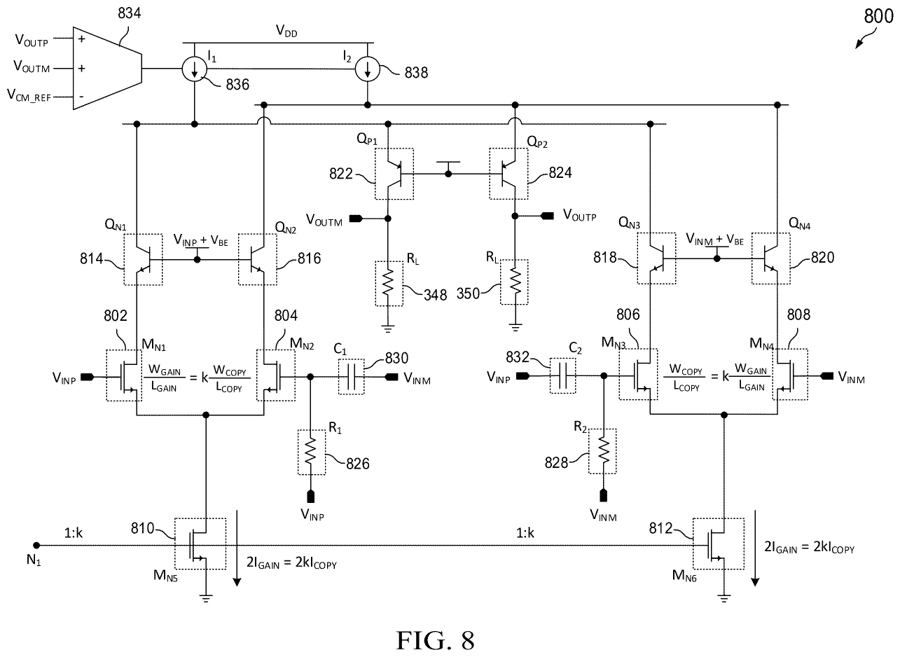

The first NPN transistor (Q_{N1}) 706 and the second NPN transistor (Q_{N2}) 708 are biased with a voltage offset of V_{REF}+V_{BE} above their respective source terminals. This configuration, combined with the existing differential pair formed by the first n-channel transistor (M_{N1}) 314 and the second n-channel transistor (M_{N2}) 316, enhances the rejection of second-order effects and power supply variations while better matching the operating conditions in the open-loop gain stage 800 in FIG. 8 and improve its common-mode rejection ratio (CMRR).

The closed-loop stage 700 includes the active current generation network 401 that implements the improvements from FIG. 4. This section provides dynamic current adjustment and improved stability across operating conditions. The drain terminal of the fifth p-channel transistor (M_{P5}) 402 couples to the control terminal of the first n-channel transistor (M_{N1}) 314 at node (N₂). Through this connection, the dynamic current adjustment directly influences the operating point of the differential pair, providing more precise control over gain stability.

In embodiments, the first current (I₁) is generated using the first startup current source (I₁) 702. However, the first current source (I₁) 702 is optional and the first current (I₁) can be generated using the active current generation network 401. The second current (I₂) is formed from the startup current (I_{STARTUP}) 710 and the current from the fourth current mirror that includes the sixth p-channel transistor (M_{P6}) 404.

FIG. 8 illustrates a schematic of an embodiment open-loop gain stage 800, which may be implemented as the open-loop gain stage 204 of FIG. 2. The open-loop gain stage 800 couples to the closed-loop stage 700 in FIG. 7 at node (N₁). The open-loop gain stage 800 builds upon the architecture of the open-loop gain stage 304 of FIG. 3 and the open-loop gain stage 600 of FIG. 6, which now includes a double differential pair with transconductance (gm) boosting. The functional and structural descriptions of components previously discussed with respect to FIGS. 3 and 6 are not repeated here for the brevity of discussion.

The open-loop gain stage 800 includes a first n-channel transistor (M_{N1}) 802, a second n-channel transistor (M_{N2}) 804, a third n-channel transistor (M_{N3}) 806, a fourth n-channel transistor (M_{N4}) 808, a fifth n-channel transistor (M_{N5}) 810, a sixth n-channel transistor (M_{N6}) 812, a first NPN transistor (Q_{N1}) 814, a second NPN transistor (Q_{N2}) 816, a third NPN transistor (M_{N3}) 818, a fourth NPN transistor (Q_{N4}) 820, a first PNP transistor (Q_{P1}) 822, a second PNP transistor (Q_{P2}) 824, a first resistor (R₁) 826, a second resistor (R₂) 828, a first capacitor (C₁) 830, a second capacitor (C₂) 832, a common-mode feedback controller 834, a first current source (I₁) 836, a second current source (I₂) 838, the first load resistor (R_{L}) 348, and the second load resistor (R_{L}) 350, which may (or may not) be arranged as shown. Open-loop gain stage 800 may include additional components not shown.

Open-loop gain stage 800 is arranged as a double differential pair with transconductance (gm) boosting. The first differential pair is formed by the first n-channel transistor (M_{N1}) 802 and the second n-channel transistor (M_{N2}) 804. The third n-channel transistor (M_{N3}) 806 and the fourth n-channel transistor (M_{N4}) 808 form the second differential pair.

The control terminal of the second n-channel transistor (M_{N2}) 804 of the first differential pair includes a first RC filter formed by the first resistor (R₁) 826 and the first capacitor (C₁) 830, which is coupled to the negative input voltage (V_{INM}). The control terminal of the third n-channel transistor (M_{N3}) 806 of the second differential pair includes a second RC filter formed by the second resistor (R₂) 828 and the second capacitor (C₂) 832, which is coupled to the positive input voltage (V_{INP}). The first and second RC networks provide high-pass filtering and DC-level shifting.

Transconductance (gm) boosting is achieved through the double differential pair configuration and the first capacitor (C₁) 830 and the second capacitor (C₂) 832. As the positive input voltage (V_{INP}) can differ significantly from the negative input voltage (V_{INM}) double differential pair is introduced.

The RC filters allow the open-loop gain stage 800 to operate with different DC levels at the positive input voltage (V_{INP}) and the negative input voltage (V_{INM}) while maintaining consistent differential gain for AC signals. The RC filters block DC and low-frequency components, providing proper biasing at their respective transistors.

The first differential pair operates in parallel with the second differential pair. By connecting these differential pairs in parallel and applying complementary input signals through the RC networks, the effective transconductance of the stage is increased compared to a single differential pair configuration. This arrangement effectively doubles the small-signal transconductance while maintaining good linearity.

The fifth n-channel transistor (M_{N5}) 810 and the sixth n-channel transistor (M_{N6}) 812, coupled to the double differential pairs, act as current sinks, establishing a bias current of 2×I_{GAIN} (which equals 2×k×I_{COPY}). This current sink configuration maintains proper current density in the differential pair formed by the differential pairs, ensuring their source terminals are held at an appropriate voltage. The scaling factor k between I_{GAIN} and I_{COPY} maintains consistent transconductance ratios between the closed-loop stage 700 and open-loop gain stage 800.

The common-mode feedback controller 834, the first current source (I₁) 836, and the second current source (I₂) 838 form a common-mode feedback circuit. The common-mode feedback circuit monitors the output voltages (V_{OUTP} and V_{OUTM}) and compares them to a common-mode reference voltage (V_{CM_REF}) using the common-mode feedback controller 834. Based on this comparison, the common-mode feedback controller 834 adjusts the first current source (I₁) 836 and the second current source (I₂) 838 to maintain the output common-mode voltage at the desired common-mode reference voltage (V_{CM_REF}) level. This feedback loop helps stabilize the DC operating point of the output stage while the folded cascode configuration allows maximum differential signal swing at output.

The first NPN transistor (Q_{N1}) 814 and the second NPN transistor (Q_{N2}) 816 have their base terminals coupled together and biased at a voltage equal to the positive input voltage (V_{INP}) plus the base-to-emitter voltage (V_{BE}) of the NPN transistors. The emitter terminals of the first NPN transistor (Q_{N1}) 814 and the second NPN transistor (Q_{N2}) 816 are coupled to the drain terminals of the first differential pair formed by the first n-channel transistor (M_{N1}) 802 and the second n-channel transistor (M_{N2}) 804. The collector terminal of the first NPN transistor (Q_{N1}) 814 couples to the first current source (I₁) 836, while the collector terminal of the second NPN transistor (Q_{N2}) 816 couples to the second current source (I₂) 838.

The first NPN transistor (Q_{N1}) 814 and the second NPN transistor (Q_{N2}) 816 function as cascode devices for the first differential pair to improve the common-mode rejection ratio and reduce other second order effects. By maintaining their base terminals at V_{INP}+V_{BE}, these transistors improve the isolation between the first differential pair and the first current source (I₁) 836 and the second current source (I₂) 838.

The third NPN transistor (Q_{N3}) 818 and the fourth NPN transistor (Q_{N4}) 820 have their base terminals coupled together and biased at a voltage equal to the negative input voltage (V_{INM}) plus the base-to-emitter voltage (V_{BE}) of the NPN transistors. The emitter terminals of the third NPN transistor (Q_{N3}) 818 and the fourth NPN transistor (Q_{N4}) 820 are coupled to the drain terminals of the second differential pair formed by the third n-channel transistor (M_{N3}) 806 and the fourth n-channel transistor (M_{N4}) 808. The collector terminal of the third NPN transistor (Q_{N3}) 818 couples to the first current source (I₁) 836, while the collector terminal of the fourth NPN transistor (Q_{N4}) 820 couples to the second current source (I₂) 838.

Similar to the first NPN transistor (Q_{N1}) 814 and the second NPN transistor (Q_{N2}) 816, the third NPN transistor (Q_{N3}) 818 and the fourth NPN transistor (Q_{N4}) 820 function as cascode devices for the second differential pair to improve the common-mode rejection ratio and other second order effects. By maintaining their control terminals at V_{INM}+V_{BE}, these transistors improve the isolation between the second differential pair and the first current source (I₁) 836 and the second current source (I₂) 838.

The first load resistor (R_{L}) 348 and the second load resistor (R_{L}) 350 are coupled between the ground terminal and the collector terminals of the first PNP transistor (Q_{P1}) 822 and the second PNP transistor (Q_{P2}) 824, respectively, in a folded stage configuration to improve the dynamic range. The common-mode feedback loop is coupled to the folded stage. The emitter terminal of the first PNP transistor (Q_{P1}) 822 receives current from the first current source (I₁) 836, while the emitter terminal of the second PNP transistor (Q_{P2}) 824 receives current from the second current source (I₂) 838.

The negative output voltage (V_{OUTM}) is generated at the node between the first load resistor (R_{L}) 348 and the collector terminal of the first PNP transistor (Q_{P1}) 822. In contrast, the positive output voltage (V_{OUTP}) is generated at the node between the second load resistor (R_{L}) 350 and the collector terminal of the second PNP transistor (Q_{P2}) 824.

Combining double differential pairs with gm boosting, cascode devices, and folded output stage with common-mode feedback provides several advantages. The architecture achieves improved linearity through the double differential pair configuration, enhanced power supply rejection through cascoding, and maximized output swing through the folded topology while maintaining stable common-mode operation through active feedback control.

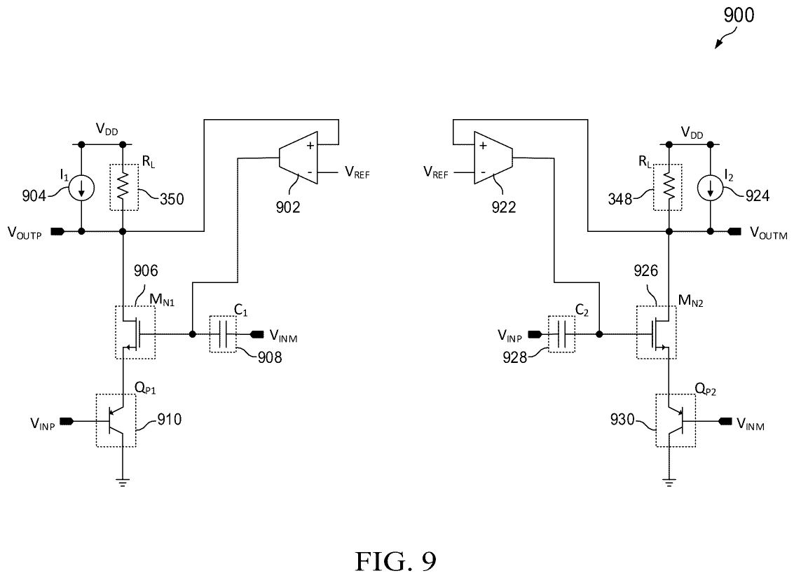

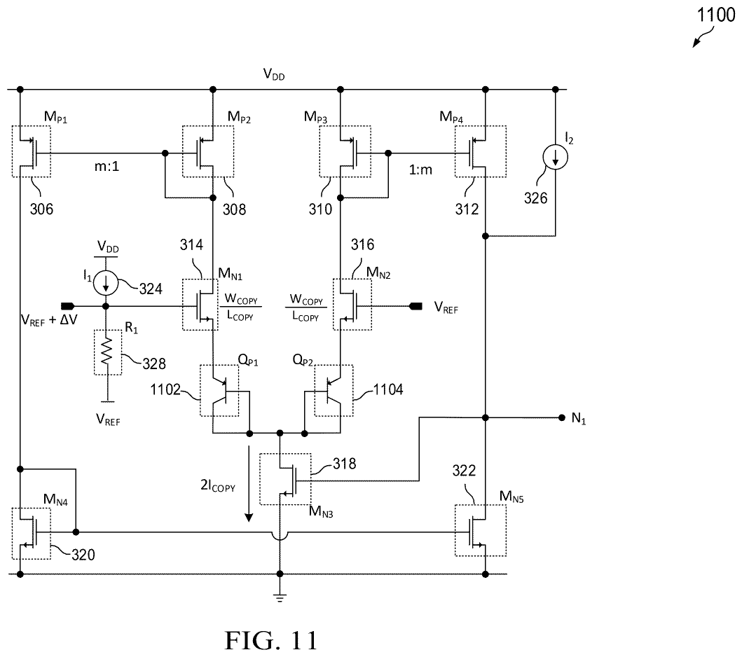

FIG. 9 illustrates a schematic of an embodiment open-loop gain stage 900, which may be implemented as the open-loop gain stage 204 of FIG. 2. The open-loop gain stage 900 couples to the closed-loop stage 1100 in FIG. 11.

After voltage/current conversions and level shifting, the voltage at node (N₁) commands the current generators (I₁) 904 and (I₂) 924; for simplicity, additional mirrors and circuitry are not shown here.

The open-loop gain stage 900 builds upon the architecture of the open-loop gain stage 304 of FIG. 3, the open-loop gain stage 600 of FIG. 6, and the open-loop gain stage 800 of FIG. 8, which extends the disclosed features to architectures with additional gain stages. The functional and structural descriptions of components previously discussed are not repeated here for the brevity of discussion.

The open-loop gain stage 900 includes a first common-mode feedback controller 902, a second common-mode feedback controller 922, a first current source (I₁) 904, a second current source (I₂) 924, a first n-channel transistor (M_{N1}) 906, a second n-channel transistor (M_{N2}) 926, a first capacitor (C₁) 908, a second capacitor (C₂) 928, a first PNP transistor (Q_{P1}) 910, a second PNP transistor (Q_{P2}) 930, the first load resistor (R_{L}) 348, and the second load resistor (R_{L}) 350, which may (or may not) be arranged as shown. Open-loop gain stage 900 may include additional components not shown.

The open-loop gain stage 900 implements a mixed-technology differential architecture using MOSFETs and bipolar devices. The first n-channel transistor (M_{N1}) 906 pairs with the first PNP transistor (Q_{P1}) 910 to form a first vertical differential pair, while the second n-channel transistor (M_{N2}) 926 pairs with the second PNP transistor (Q_{P2}) 930 to form a second vertical differential pair.

Each vertical differential pair receives complementary input signals. The first vertical pair receives the negative input voltage (V_{INM}) through the first capacitor (C₁) 908 at the first n-channel transistor (M_{N1}) 906 and the positive input voltage (V_{INP}) directly at the first PNP transistor (Q_{P1}) 910. Similarly, the second vertical pair receives the positive input voltage (V_{INP}) through the second capacitor (C₂) 928 at the second n-channel transistor (M_{N2}) 926 and the negative input voltage (V_{INM}) directly at the second PNP transistor (Q_{P2}) 930. The first capacitor (C₁) 908 and the second capacitor (C₂) 928 provide AC coupling for the MOSFET inputs.

The first common-mode feedback controller 902 and the second common-mode feedback controller 922 monitor their respective output voltages (V_{OUTP} and V_{OUTM}) against the reference voltage (V_{REF}). These controllers adjust the gate voltages of the first n-channel transistor (M_{N1}) 906 and the second n-channel transistor (M_{N2}) 926, respectively, to regulate the currents flowing in the vertical differential couples and to maintain proper output common-mode levels. The first load resistor (R_{L}) 348 and the second load resistor (R_{L}) 350 convert the differential currents into output voltages.

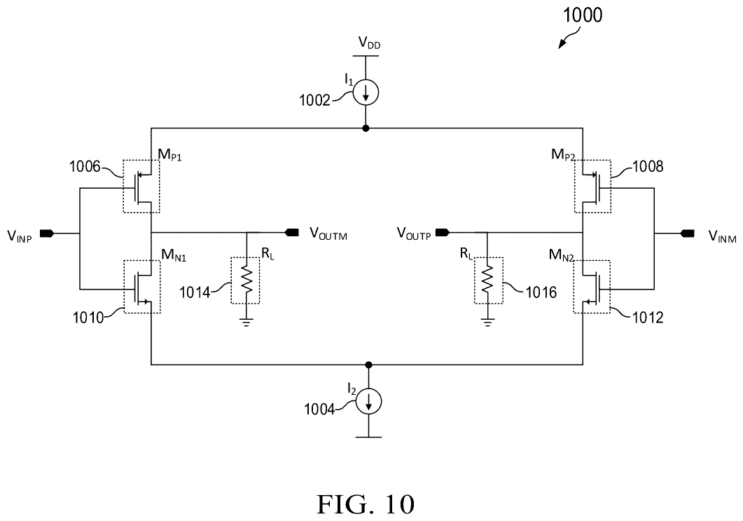

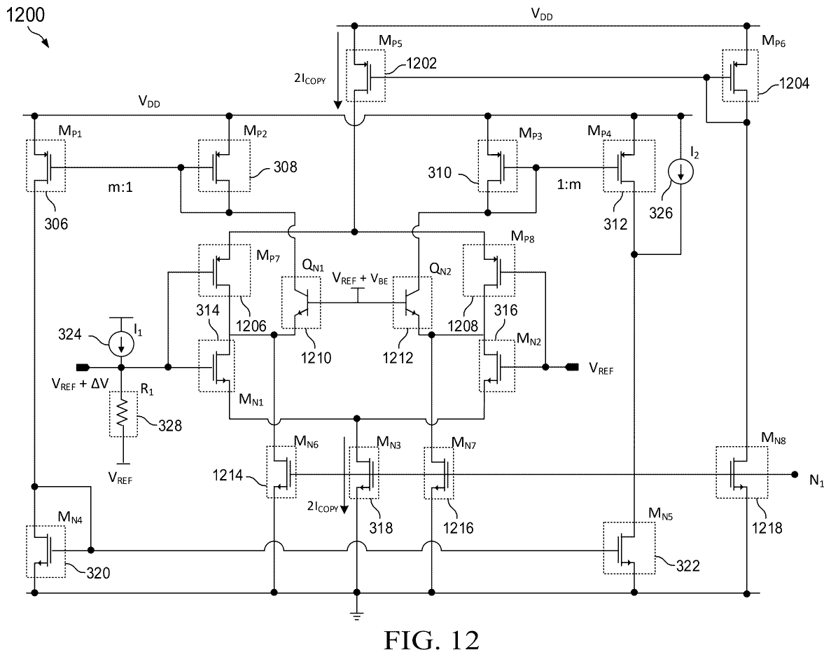

FIG. 10 illustrates a schematic of an embodiment open-loop gain stage 1000, which may be implemented as the open-loop gain stage 204 of FIG. 2. The open-loop gain stage 1000 couples to the closed-loop stage 1200 in FIG. 12.

After voltage/current conversions and level shifting, the voltage at node (N₁) commands the current generators (I₁) 1002 and (I₂) 1004; for simplicity, additional mirrors and circuitry are not shown here.

The open-loop gain stage 1000 builds upon the architecture of the open-loop gain stage 304 of FIG. 3, the open-loop gain stage 600 of FIG. 6, and the open-loop gain stage 800 of FIG. 8. The functional and structural descriptions of components previously discussed are not repeated here for the brevity of discussion.

The open-loop gain stage 1000 includes a first current source (I₁) 1002, a second current source (I₂) 1004, a first p-channel transistor (M_{P1}) 1006, a second p-channel transistor (M_{P2}) 1008, a first n-channel transistor (M_{N1}) 1010, a second n-channel transistor (M_{N2}) 1012, a first resistor load (R_{L}) 1014, and a second resistor load (R_{L}) 1016, which may (or may not) be arranged as shown. Open-loop gain stage 1000 may include additional components not shown.

The open-loop gain stage 1000 implements an inverter-based architecture using complementary PMOS and NMOS devices. The first p-channel transistor (M_{P1}) 1006 pairs with the first n-channel transistor (M_{N1}) 1010 to form a first inverter, while the second p-channel transistor (M_{P2}) 1008 pairs with the second n-channel transistor (M_{N2}) 1012 to form a second inverter.

The first current source (I₁) 1002 and the second current source (I₂) 1004 establish bias currents for the inverter pairs. The first resistor load (R_{L}) 1014 and the second resistor load (R_{L}) 1016 set the gain of the open-loop gain stage 1000, together with the transconductance of the inverters. The negative input voltage (V_{INM}) drives the first inverter to generate the positive output voltage (V_{OUTP}), while the positive input voltage (V_{INP}) drives the second inverter to generate the negative output voltage (V_{OUTP}).

This complementary inverter configuration provides voltage gain through the transconductance of both PMOS and NMOS devices operating in parallel while maintaining balanced operation through the symmetric structure. Folded structures not shown here for simplicity can be used to increase the output dynamic range of the stage and to improve second-order effects.

FIG. 11 illustrates a schematic of an embodiment closed-loop stage 1100, which may be implemented as the closed-loop stage 202 of FIG. 2. Closed-loop stage 1100 couples to the open-loop gain stage 900 in FIG. 9.

The voltage at node (N₁) can command current sources (I₁) 904 and (I₂) 924 in the open-loop gain stage in FIG. 9. In embodiments, the closed-loop stage 1100 works in combination with the open-loop gain stage 900 of FIG. 9. The closed-loop stage 1100 builds upon the architecture of closed-loop stage 500 of FIG. 5. The functional and structural descriptions of components previously discussed concerning FIG. 5 are not repeated here for the brevity of discussion.

The closed-loop stage 1100 replaces the ninth n-channel transistor (M_{N9}) 502 and the tenth n-channel transistor (M_{N10}) 504 with a first PNP transistor (Q_{P1}) 1102 and a second PNP transistor (Q_{P2}) 1104, respectively. The first PNP transistor (Q_{P1}) 1102 and the second PNP transistor (Q_{P2}) 1104 are configured as diode-connected devices coupled to the first n-channel transistor (M_{N1}) 314 and the second n-channel transistor (M_{N2}) 316, respectively. This configuration creates a mixed-technology differential pair using PNP and NMOS devices in a vertical arrangement.

The vertical arrangement of PNP and NMOS devices provides complementary transconductance characteristics. By combining the transconductance of both device types in series, the circuit transconductance and, thus, the noise is optimized concerning the standard differential couple, considering the same power consumption. The diode connection of the first PNP transistor (Q_{P1}) 1102 and the second PNP transistor (Q_{P2}) 1104 emulates the vertical differential pair structures in FIG. 9 and ensures their proper biasing.

FIG. 12 illustrates a schematic of an embodiment closed-loop stage 1200, which may be implemented as the closed-loop stage 202 of FIG. 2. Closed-loop stage 1200 couples to the open-loop gain stage 1000 in FIG. 10.

The voltage at node (N₁) can command current sources (I₁) 1002 and (I₂) 1004 in the open-loop gain stage in FIG. 10. In embodiments, the closed-loop stage 1200 is combined with the open-loop gain stage 1000 of FIG. 10. The closed-loop stage 1200 builds upon the architecture of closed-loop stage 302 of FIG. 3. The functional and structural descriptions of components previously discussed are not repeated here for the sake of the brevity of the discussion.

Concerning the closed-loop stage 302, closed-loop stage 1200 additionally includes a fifth p-channel transistor (M_{P5}) 1202, a sixth p-channel transistor (M_{P6}) 1204, a seventh p-channel transistor (M_{P7}) 1206, an eighth p-channel transistor (M_{P8}) 1208, a first NPN transistor (Q_{N1}) 1210, a second NPN transistor (Q_{N2}) 1212, a sixth n-channel transistor (M_{N6}) 1214, a seventh n-channel transistor (M_{N7}) 1216, and an eighth n-channel transistor (M_{N8}) 1218, which may (or may not) be arranged as shown.

The fifth p-channel transistor (M_{P5}) 1202 and the sixth p-channel transistor (M_{P6}) 1204 couple to provide a current (2×I_{COPY} to the differential pair formed by the first n-channel transistor (M_{N1}) 314 and the second n-channel transistor (M_{N2}) 316.

The seventh p-channel transistor (M_{P7}) 1206 and eighth p-channel transistor (M_{P8}) 1208 form complementary pairs with the first NPN transistor (Q_{N1}) 1210 and the second NPN transistor (Q_{N2}) 1212, respectively. The first NPN transistor (Q_{N1}) 1210 and the second NPN transistor (Q_{N2}) 1212 are biased with their base terminals set to: V_{REF}+V_{BE}.

The sixth n-channel transistor (M_{N6}) 1214 and seventh n-channel transistor (M_{N7}) 1216 couple to the differential pair to mirror the current (2×I_{COPY}). The eighth n-channel transistor (M_{N8}) 1218 couples to node (N₁) to provide the scaled bias current to the open-loop gain stage. This configuration with complementary pairs and current mirroring provides appropriate bias currents for an inverter-based open-loop gain stage while maintaining consistent gain control across process and temperature variations.

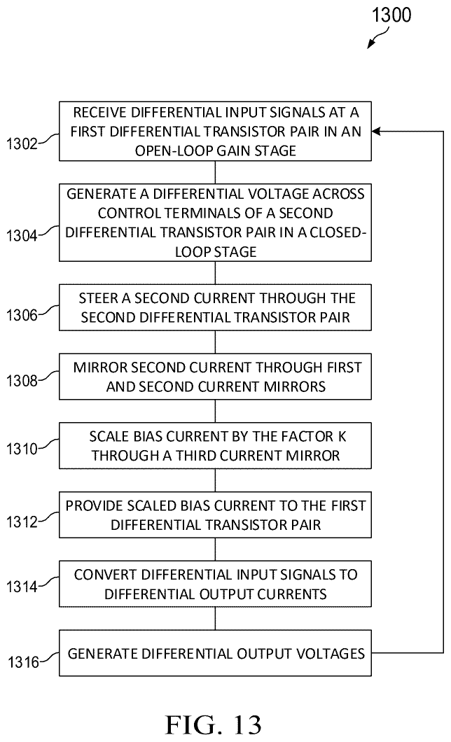

FIG. 13 illustrates a flowchart of an embodiment method 1300 for operating an analog front-end circuit in a hard disk drive pre-amplifier. The method leverages the interaction between a closed-loop stage and an open-loop gain stage to achieve gain control while maintaining high performance. It is noted that all steps outlined in the method are not necessarily required and can be optional. Further, changes to the arrangement of the steps, removal of one or more steps and path connections, and addition of steps and path connections are similarly contemplated.

The method operates on an architecture where the closed-loop stage includes a scaled copy of the core amplification elements from the open-loop gain stage. This copying approach allows the closed-loop stage to monitor and compensate for variations in device characteristics without introducing additional components into the main signal path. By separating the gain control function from the signal amplification path, the architecture preserves the bandwidth and noise advantages of open-loop operation while achieving the stability benefits of closed-loop control.

By scaling and matching between the two stages, variations in process, voltage, and temperature that affect the copy stage are compensated in the main signal path. This compensation occurs without degrading the signal amplification stage's dynamic range, noise or frequency response. The method demonstrates how the closed-loop stage can dynamically adjust bias conditions to maintain consistent gain across operating conditions while allowing the open-loop stage to operate with minimal active components in the signal path.

At step 1302, differential input signals are received at a first differential transistor pair in an open-loop gain stage, where load resistors couple to outputs of the first differential transistor pair.

In embodiments, the differential input signals include a positive input voltage (V_{INP}) and a negative input voltage (V_{INM}) that couple to respective control terminals of the first differential transistor pair.

In embodiments, RC networks comprising resistor-capacitor combinations may couple between the input voltages and the control terminals to provide AC coupling and DC level shifting.

In embodiments, the load resistors couple between a supply voltage and respective drain terminals of the first differential transistor pair to convert differential currents into output voltages. The load resistors may be matched to maintain balanced operation and consistent gain between the differential paths.

In embodiments, the first differential transistor pair may include n-channel transistors configured to provide low noise amplification with wide bandwidth due to minimal parasitic capacitance in the signal path.

At step 1304, a differential voltage is generated across control terminals of a second differential transistor pair in a closed-loop stage by flowing a first current through a reference resistor. The second differential transistor pair has width-to-length ratios scaled by a factor k relative to the first differential transistor pair.

In embodiments, the reference resistor is implemented using the same resistor type as the load resistors to maintain consistent temperature and process tracking.

The first current flows through the reference resistor to create a known voltage drop ΔV that establishes the operating point of the second differential transistor pair.

The width-to-length ratio scaling between the first and second differential pairs follows the relationship

$$\frac{{W}_{GAIN}}{{L}_{GAIN}} = k \times \frac{{W}_{COPY}}{{L}_{COPY}} ,$$

where W_{COPY} and L_{COPY} are the dimensions of transistors in the second differential pair, and W_{GAIN} and L_{GAIN} are the dimensions of transistors in the first differential pair. This geometric scaling ensures that variations in transistor parameters like threshold voltage and mobility affect both pairs proportionally.

The factor k may be selected based on power consumption and matching requirements, where, chosen the size and the power consumption of the differential couple in the open-loop stage depend on the design requirements. Larger k values reduce device sizes and power consumption of the closed-loop stage but impact on matching and gain controlling accuracy of the open-loop stage, while smaller k values improve matching and increase power consumption of the closed-loop stage such as improve gain controlling accuracy of the open-loop stage.

In embodiments, degeneration transistors may couple to source terminals of the second differential pair to enhance matching and increase linear operating range.

At step 1306, a second current is steered through the second differential transistor pair based on the differential voltage generated in step 1304. The differential voltage ΔV applied across the control terminals creates an imbalance in the second differential transistor pair, causing the second current to split unequally between the two transistors.

The ratio of current splitting depends on the magnitude of ΔV and the transconductance of the second differential pair. Proportional to the positive ΔV amplitude, a larger portion of the second current flows through one side of the differential pair, while a smaller portion flows through the other side. The total second current remains constant, maintained by a current sink coupled to the common source terminal of the second differential transistor pair.

In embodiments, cascode devices may couple between the drain terminals of the second differential pair and subsequent current mirrors to improve output impedance and power supply rejection. The cascode devices may be biased at a voltage equal to the input common-mode voltage plus one base-to-emitter voltage (V_{BE}) to ensure proper operation. The second differential pair may include source degeneration to increase linear operating range and improve matching between the transistors.

At step 1308, the second current is mirrored through first and second current mirrors to generate a bias current. In embodiments, the first current mirror includes a first p-channel transistor and a second p-channel transistor, while the second current mirror includes a third p-channel transistor and a fourth p-channel transistor. Each current mirror is configured with a ratio of 1 to m (1:m).

The differential currents from the second differential pair feed into the current mirrors. The first current mirror and the second current mirror create a current scaling network that translates the differential currents into a single-ended bias current while maintaining accurate current ratios. When the second differential pair steers current in response to ΔV, these current mirrors convey the differential current into the bias current through the complementary scaling.

Cascode devices may couple between the current mirrors to increase output impedance and improve mirroring accuracy. The cascode devices may include n-channel transistors with control terminals biased at a fixed voltage above their respective source terminals.

The value of m may be selected based on desired current scaling and power consumption. In embodiments, the current mirrors may include additional devices for startup operation to ensure proper initialization of the bias current.

At step 1310, the bias current is scaled by the factor k through a third current mirror to create a scaled bias current. In embodiments, the third current mirror includes input and output transistors with width-to-length ratios scaled to provide a 1:k current multiplication.

In embodiments, the input transistor of the third current mirror receives the bias current generated by the current mirrors. In contrast, the output transistor generates the scaled bias current that is k times larger. The scaling maintains the mathematical relationship between transconductance in the closed-loop and open-loop stages through the equation: gm_{GAIN}=k×gm_{COPY}, where gm_{GAIN} represents the transconductance of the first differential pair and gm_{COPY} represents the transconductance of the second differential pair.

The third current mirror may include cascode devices to improve accuracy of the k:1 scaling ratio across different operating conditions.

In embodiments, a compensation capacitor may couple between the input and output nodes of the third current mirror to enhance frequency stability of the bias current scaling.

In embodiments, the third current mirror may split into multiple parallel devices with matched layouts to improve current matching and reduce mismatch from process variations. The factor k may vary depending on the desired trade-off between power consumption and device matching requirements.

At step 1312, the scaled bias current is provided to the first differential transistor pair to establish transconductance in the open-loop gain stage proportional to transconductance in the closed-loop stage. The scaled bias current flows through a current sink transistor coupled to the common source terminal of the first differential pair. The current sink configuration maintains proper current density in the first differential pair by ensuring their source terminals are held at an appropriate voltage.

The transconductance relationship between the open-loop gain stage and closed-loop stage follows from the device physics of the transistors. Since the width-to-length ratios in the closed-loop stage are scaled by factor k, the currents are scaled by the same factor k, and the process parameters are matched, the transconductance of the first differential pair equals k times the transconductance of the second differential pair

At step 1314, the differential input signals are converted to differential output currents through the transconductance of the first differential transistor pair. The positive input voltage (V_{INP}) and negative input voltage (V_{INM}) couple to respective control terminals of the first differential transistor pair. The transconductance of the first differential pair, established by the scaled bias current from step 1312, converts the differential voltage (V_{INP}−V_{INM}) into differential output currents. The conversion maintains consistent voltage gain on the load resistor (R_{L}) across process, voltage, and temperature variations due to the bias current scaling established by the closed-loop stage.

At step 1316, differential output voltages are generated by flowing the differential output currents through the load resistors. The load resistors convert the differential output currents into a positive output voltage (V_{OUTP}) and a negative output voltage (V_{OUTM}). The conversion maintains consistent voltage gain across process, voltage, and temperature variations.

In embodiments, the load resistors couple between a supply voltage and respective drain terminals of the first differential transistor pair. The load resistors may be implemented using the same resistor type as the reference resistor in the closed-loop stage to maintain consistent temperature and process tracking.

Method 1300 may proceed from step 1316 back to step 1302 in a continuous operation, maintaining consistent gain across process, voltage, and temperature variations while preserving the bandwidth and noise advantages of open-loop operation.

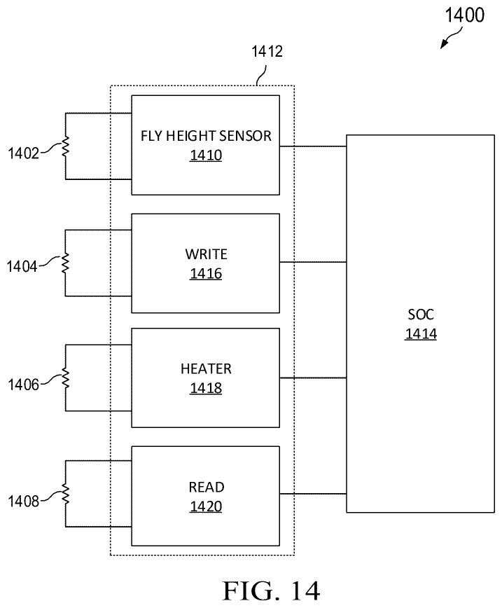

FIG. 14 illustrates a block diagram of a pre-amplifier 1412 that is placed on the disk drive head stack assembly of a hard disk drive. In embodiments, pre-amplifier 1412 includes the analog front-end circuit 200.

The disk drive head stack assembly slides over the disk. The pre-amplifier 1412 includes a fly height sensor 1410. In embodiments, the fly height sensor 1410 includes a biasing circuit and an amplifier (not shown). The fly height sensor 1410 is coupled to a resistive sensor 1402, which may be implemented as the resistive sensor (R_{SNS}) 106. The resistive sensor 1402 monitors the fly height between the disk drive head and the disk itself.

A write resistor 1404 is coupled to the write circuit 1416 (for writing to the disk), a heater resistor 1406 is coupled to the heater circuit 1418 (for controlling the fly height spacing), and a read resistor 1408 is coupled to the read circuit 1420 (for reading from the disk). The fly height sensor 1410, write circuit 1416, heater circuit 1418, and read circuit 1420 are coupled to a system-on-chip (SoC) 1414 for processing.

A first aspect relates to an analog front-end circuit, comprising an open-loop gain stage including a first differential transistor pair comprising a first transistor and a second transistor with first width-to-length ratios, load resistors coupled to outputs of the first transistor and the second transistor, and a current sink coupled to source terminals of the first transistor and the second transistor; and a closed-loop stage including a second differential transistor pair comprising a third transistor and a fourth transistor with second width-to-length ratios scaled by a factor 1/k relative to the first width-to-length ratios, a reference resistor coupled to receive a first current to generate a differential voltage across control terminals of the third transistor and the fourth transistor, wherein the reference resistor matches a resistor type of the first load resistors, a first current mirror and a second current mirror coupled to steer a second current through the second differential transistor pair based on the differential voltage, and a third current mirror configured to scale the second current by the factor k to generate a bias current for the current sink.

In a first implementation form of the analog front-end circuit, according to the first aspect as such, the first current mirror and the second current mirror have a ratio of 1 to m, where m is an integer or fractional number greater than zero.

In a second implementation form of the analog front-end circuit, according to the first aspect as such or any preceding implementation form of the first aspect, the analog front-end circuit further comprising a first cascode device and a second cascode device coupled between drain terminals of the third transistor and the fourth transistor and the first current mirror and second current mirror, respectively.

In a third implementation form of the analog front-end circuit, according to the first aspect as such or any preceding implementation form of the first aspect, the first cascode device and the second cascode device are biased at a voltage equal to an input common-mode voltage plus one base-to-emitter voltage.

In a fourth implementation form of the analog front-end circuit, according to the first aspect as such or any preceding implementation form of the first aspect, the analog front-end circuit further comprising a first RC network and a second RC network coupled between differential input signals and control terminals of the first transistor and the second transistor, respectively, wherein the first RC network and the second RC network provide AC coupling and DC level shifting.

In a fifth implementation form of the analog front-end circuit, according to the first aspect as such or any preceding implementation form of the first aspect, the analog front-end circuit further comprising a first diode-connected transistor and a second diode-connected transistor coupled to source terminals of the third transistor and fourth transistor, respectively, wherein the first and second diode-connected transistors have width-to-length ratios matching the second width-to-length ratios.

In a sixth implementation form of the analog front-end circuit, according to the first aspect as such or any preceding implementation form of the first aspect, the factor k is selected based on power consumption and matching requirements between the first differential transistor pair and the second differential transistor pair.

In a seventh implementation form of the analog front-end circuit, according to the first aspect as such or any preceding implementation form of the first aspect, the first transistor and the second transistor comprise n-channel metal-oxide-semiconductor field-effect transistors (MOSFETs), the open-loop gain stage further comprises a first PNP transistor coupled to the first transistor and a second PNP transistor coupled to the second transistor to form first and second vertical differential pairs, and the first PNP transistor and second PNP transistor receive complementary input signals relative to the first transistor and second transistor.

In an eighth implementation form of the analog front-end circuit, according to the first aspect as such or any preceding implementation form of the first aspect, the analog front-end circuit further comprising a compensation capacitor coupled between input and output nodes of the third current mirror.

In a ninth implementation form of the analog front-end circuit, according to the first aspect as such or any preceding implementation form of the first aspect, the analog front-end circuit further comprising a first startup current source and a second startup current source coupled to the closed-loop stage.

A second aspect relates to a method of operating an analog front-end circuit, the method comprising generating a differential voltage across control terminals of a first differential transistor pair by flowing a first current through a reference resistor; steering a second current through the first differential transistor pair based on the differential voltage; mirroring the second current through first and second current mirrors; scaling the mirrored second current by a factor k through a third current mirror; providing the scaled second current to a current sink coupled to a second differential transistor pair, wherein the second differential transistor pair has transistors with width-to-length ratios k times larger than transistors in the first differential transistor pair; receiving differential input signals at control terminals of the second differential transistor pair; and generating differential output voltages across load resistors coupled to outputs of the second differential transistor pair, wherein the load resistors match a resistor type of the reference resistor.

In a first implementation form of the method, according to the second aspect as such, the first current mirror and the second current mirror have a ratio of 1 to m, where m is an integer or fractional number greater than zero.

In a second implementation form of the method, according to the second aspect as such or any preceding implementation form of the second aspect, the method further includes providing AC coupling and DC level shifting for the differential input signals through RC networks.

In a third implementation form of the method, according to the second aspect as such or any preceding implementation form of the second aspect, the method further includes compensating frequency response of the third current mirror using a compensation capacitor.

A third aspect relates to an analog front-end circuit, comprising an open-loop gain stage including a first and second complementary transistor pairs configured as inverters, first and second resistors coupled to set DC operating points for the inverters, and first and second RC networks coupled to provide AC coupling for differential input signals; and a closed-loop stage including a differential transistor pair having transistors with width-to-length ratios scaled by a factor 1/k relative to transistors in the first and second complementary transistor pairs, a reference resistor coupled to receive a first current to generate a differential voltage, first and second current mirrors coupled to steer a second current through the differential transistor pair based on the differential voltage, third and fourth complementary transistor pairs biased at ground plus a base-to-emitter voltage, and a third current mirror configured to scale the second current by the factor k to generate bias currents for the first and second complementary transistor pairs.

In a first implementation form of the analog front-end circuit, according to the third aspect as such, the first and second complementary transistor pairs each comprise a p-channel transistor, an n-channel transistor, a PNP transistor, an NPN transistor, or any combination thereof.

In a second implementation form of the analog front-end circuit, according to the third aspect as such or any preceding implementation form of the third aspect, the first and second resistors match a resistor type of the reference resistor.

In a third implementation form of the analog front-end circuit, according to the third aspect as such or any preceding implementation form of the third aspect, the third and fourth complementary transistor pairs provide cascode operation.

In a fourth implementation form of the analog front-end circuit, according to the third aspect as such or any preceding implementation form of the third aspect, the first current mirror and the second current mirror have a ratio of 1 to m, where m is an integer or fractional number greater than zero.

In a second implementation form of the analog front-end circuit, according to the third aspect as such or any preceding implementation form of the third aspect, the analog front-end circuit further comprising a compensation capacitor coupled between input and output nodes of the third current mirror.

Although the description has been described in detail, it should be understood that various changes, substitutions, and alterations may be made without departing from the spirit and scope of this disclosure as defined by the appended claims. The same elements are designated with the same reference numbers in the various figures. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

Various aspects of the disclosure can be combined and implemented in different ways based on specific applications. The circuits' transistors may include metal-oxide-semiconductor field-effect transistors (MOSFETs) and bipolar junction transistors (BJTs) in any combination.

The specification and drawings are, accordingly, to be regarded simply as an illustration of the disclosure as defined by the appended claims, and are contemplated to cover any and all modifications, variations, combinations, or equivalents that fall within the scope of the present disclosure.

What is claimed is:

1. An analog front-end circuit, comprising:
an open-loop gain stage including:
a first differential transistor pair comprising a first transistor and a second transistor with first width-to-length ratios,
load resistors coupled to outputs of the first transistor and the second transistor, and
a current sink coupled to source terminals of the first transistor and the second transistor; and
a closed-loop stage including:
a second differential transistor pair comprising a third transistor and a fourth transistor with second width-to-length ratios scaled by a factor 1/k relative to the first width-to-length ratios,
a reference resistor coupled to receive a first current to generate a differential voltage across control terminals of the third transistor and the fourth transistor, wherein the reference resistor matches a resistor type of the first load resistors,
a first current mirror and a second current mirror coupled to steer a second current through the second differential transistor pair based on the differential voltage, and
a third current mirror configured to scale the second current by the factor k to generate a bias current for the current sink.

2. The analog front-end circuit of claim 1, wherein the first current mirror and the second current mirror have a ratio of 1 to m, where m is an integer or fractional number greater than zero.

3. The analog front-end circuit of claim 1, further comprising a first cascode device and a second cascode device coupled between drain terminals of the third transistor and the fourth transistor and the first current mirror and second current mirror, respectively.

4. The analog front-end circuit of claim 3, wherein the first cascode device and the second cascode device are biased at a voltage equal to an input common-mode voltage plus one base-to-emitter voltage.

5. The analog front-end circuit of claim 1, further comprising a first RC network and a second RC network coupled between differential input signals and control terminals of the first transistor and the second transistor, respectively, wherein the first RC network and the second RC network provide AC coupling and DC level shifting.

6. The analog front-end circuit of claim 1, further comprising a first diode-connected transistor and a second diode-connected transistor coupled to source terminals of the third transistor and fourth transistor, respectively, wherein the first and second diode-connected transistors have width-to-length ratios matching the second width-to-length ratios.

7. The analog front-end circuit of claim 1, wherein the factor k is selected based on power consumption and matching requirements between the first differential transistor pair and the second differential transistor pair.

8. The analog front-end circuit of claim 1,
wherein the first transistor and the second transistor comprise n-channel metal-oxide-semiconductor field-effect transistors (MOSFETs),
wherein the open-loop gain stage further comprises a first PNP transistor coupled to the first transistor and a second PNP transistor coupled to the second transistor to form first and second vertical differential pairs, and
wherein the first PNP transistor and second PNP transistor receive complementary input signals relative to the first transistor and second transistor.

9. The analog front-end circuit of claim 1, further comprising a compensation capacitor coupled between input and output nodes of the third current mirror.

10. The analog front-end circuit of claim 1, further comprising a first startup current source and a second startup current source coupled to the closed-loop stage.

11. A method of operating an analog front-end circuit, the method comprising:
generating a differential voltage across control terminals of a first differential transistor pair by flowing a first current through a reference resistor;
steering a second current through the first differential transistor pair based on the differential voltage;
mirroring the second current through first and second current mirrors;
scaling the mirrored second current by a factor k through a third current mirror;
providing the scaled second current to a current sink coupled to a second differential transistor pair, wherein the second differential transistor pair has transistors with width-to-length ratios k times larger than transistors in the first differential transistor pair;
receiving differential input signals at control terminals of the second differential transistor pair; and
generating differential output voltages across load resistors coupled to outputs of the second differential transistor pair, wherein the load resistors match a resistor type of the reference resistor.

12. The method of claim 11, wherein the first current mirror and the second current mirror have a ratio of 1 to m, where m is an integer or fractional number greater than zero.

13. The method of claim 11, further comprising providing AC coupling and DC level shifting for the differential input signals through RC networks.

14. The method of claim 11, further comprising compensating frequency response of the third current mirror using a compensation capacitor.

15. An analog front-end circuit, comprising:
an open-loop gain stage including:
a first and second complementary transistor pairs configured as inverters,
first and second resistors coupled to set DC operating points for the inverters, and
first and second RC networks coupled to provide AC coupling for differential input signals; and
a closed-loop stage including:
a differential transistor pair having transistors with width-to-length ratios scaled by a factor 1/k relative to transistors in the first and second complementary transistor pairs,
a reference resistor coupled to receive a first current to generate a differential voltage,
first and second current mirrors coupled to steer a second current through the differential transistor pair based on the differential voltage,
third and fourth complementary transistor pairs biased at ground plus a base-to-emitter voltage, and
a third current mirror configured to scale the second current by the factor k to generate bias currents for the first and second complementary transistor pairs.

16. The analog front-end circuit of claim 15, wherein the first and second complementary transistor pairs each comprise a p-channel transistor, an n-channel transistor, a PNP transistor, an NPN transistor, or any combination thereof.

17. The analog front-end circuit of claim 15, wherein the first and second resistors match a resistor type of the reference resistor.

18. The analog front-end circuit of claim 15, wherein the third and fourth complementary transistor pairs provide cascode operation.

19. The analog front-end circuit of claim 15, wherein the first current mirror and the second current mirror have a ratio of 1 to m, where m is an integer or fractional number greater than zero.

20. The analog front-end circuit of claim 15, further comprising a compensation capacitor coupled between input and output nodes of the third current mirror.
